(19) United States
(12) Patent Application Publication
(10) Pub. No.: US 2026/0346749 A1
(43) Pub. Date: Nov. 5, 2026

(54) Method for Determining an Internal Resistance of an Energy Storage Device of a Motor Vehicle, Computer Program and/or Computer Readable Medium, Data Processing Device, Battery Control Device and Motor Vehicle

(71) Applicant: Bayerische Motoren Werke Aktiengesellschaft, Muenchen (DE)

(72) Inventors: Simon ERHARD, Geltendorf (DE); Jacob HAMAR, Muenchen (DE); Johannes STURM, Muenchen (DE); Lukas WOLF, Muenchen (DE); Christoph ZOERR, Muenchen (DE)

(21) Appl. No.: 19/125,480

(22) PCT Filed: Oct. 24, 2023
(86) PCT No.: PCT/EP2023/079525

§ 371 Date: Apr. 29, 2025

(30) Foreign Application Priority Data
Oct. 31, 2022 (DE) 10 2022 128 836.6

(51) Int. Cl. B60L 53/62; B60L 55/00; B60L 58/12; B60L 58/24; G01R 31/374; G01R 31/389; H01M 10/42; H01M 10/44

(52) U.S. Cl. CPC B60L 53/62; B60L 55/00; B60L 58/12; B60L 58/24; G01R 31/374; G01R 31/389; H01M 10/425; H01M 10/443; B60L 2240/545; H01M 2010/4271; H01M 2220/20

(57) ABSTRACT

The present disclosure relates to a method for determining an internal resistance of an energy storage device of a motor vehicle, where the method includes: determining an actual state of charge of the energy storage device; determining a charging and discharging current profile for charging the energy storage device using a charging station external to the vehicle, and for discharging the energy storage device based on the actual state of charge; charging and discharging the energy storage device based on the charging and discharging current profile; determining a quantity of heat relating to the charging and discharging; and determining a power loss based on the charging and discharging current profile depending on the quantity of heat in order to determine the internal resistance.

### BACKGROUND AND SUMMARY

The present disclosure relates to a method for determining an internal resistance of an energy storage device of a motor vehicle. Furthermore, a battery management unit and a motor vehicle are provided with the data processing device. In addition or alternatively, a computer program is provided, which comprises commands which, during the execution of the program by a computer, cause this computer to execute the method at least partially. In addition or alternatively, a computer-readable medium is provided, which comprises commands which, during the execution of the commands by a computer, cause this computer to execute the method at least partially.

The internal resistance of an energy storage device or a battery store influences the available power and energy. For various uses, such as for example prediction of driving performance and/or ascertainment of a fast-charging capability, it may be necessary to determine the internal resistance of the energy storage device as exactly as possible. Taking the internal resistance into consideration, the energy storage device can be operated effectively and aging can be reduced.

The internal resistance of the energy storage device changes and in particular increases however even for particular environmental conditions and a particular state of charge of the energy storage device with increasing aging of the energy storage device, as a result of which available power and energy decrease over the life cycle of the energy storage device. Therefore, the reliable ascertainment of the internal resistance is of central importance for a multiplicity of applications.

In other words, the disclosure relates to a diagnosis of the energy storage device, in which the internal resistance is determined.

The internal resistance or its change over a life cycle of the energy storage device can be estimated for example by empirical models, such as for example an equivalent circuit diagram model.

EP 1 414 101 B1 discloses a detecting method for detecting internal resistance of a rechargeable battery to be inspected when said rechargeable battery to be inspected is charged by a constant current-constant voltage charging regime comprising a constant current charging mode and a constant voltage charging mode in that charging is commenced by said constant current charging mode at a constant current value and after the battery voltage of said rechargeable battery to be inspected reaches a given voltage value, the charging is performed by said constant voltage charging mode at a constant voltage until the termination thereof, wherein said detecting method comprises at least a step wherein an accumulated, charged electricity quantity of said rechargeable battery to be inspected in the constant voltage charging mode is obtained and a step wherein said charged electricity quantity of said rechargeable battery to be inspected obtained in the constant voltage charging mode in said step is referred to previously acquired data of a normal rechargeable battery, whereby the internal resistance of the rechargeable battery to be inspected is detected, the normal rechargeable battery corresponds to said rechargeable battery to be inspected, with respect to relationships of charged electricity quantities thereof versus internal resistances thereof when increased or decreased or their increased or decreased magnitudes in the constant voltage charging mode.

Charging of the energy storage device takes place successively by the constant current charging mode and the constant voltage charging mode. The internal resistance is ultimately ascertained by the relationship, in terms of the electricity quantity, between the battery to be inspected and a reference battery, what is known as the normal rechargeable battery. Thus, the internal resistance is ascertained indirectly by establishing the relationship.

DE 10 2019 108 607 B3 discloses a method for ascertaining a charging profile from a multiplicity of charging profiles for a current charging process for charging an electrical energy store. The method comprises ascertaining a current state of the energy store, ascertaining the charging profile from the multiplicity of charging profiles based on the current state of the energy store and charging the energy store based on the charging profile that is ascertained. The present disclosure further relates to a system for ascertaining a charging profile comprising a control unit, which is configured for performing at least part of the method, and a vehicle comprising the system.

Against the background of this prior art, the object of the present disclosure is to specify a method that is suitable for enhancing the prior art. Embodiments of the disclosure can achieve an object of specifying an alternative possibility for determining the internal resistance.

This object is achieved by the features of the present disclosure. The present disclosure includes additional optional features.

Accordingly, the object is achieved by a method for determining an internal resistance of an energy storage device of a motor vehicle. The method comprises: ascertaining an actual state of charge of the energy storage device; determining a charging and discharging current profile for charging the energy storage device by a charging station outside the vehicle and for discharging the energy storage device based on the actual state of charge; charging and discharging the energy storage device based on the charging and discharging current profile; ascertaining a heat variable relating to the charging and discharging; and ascertaining a power loss based on the charging and discharging current profile and based on the heat variable for determining the internal resistance.

The actual state of charge of the energy storage device characterizes the current state of charge of the energy storage device. Starting from the actual state of charge, the energy storage device is charged and/or discharged according to the charging and discharging current profile. The charging and discharging current profile has a charging-current profile for charging the energy storage device with a charging current and a discharge-current profile for discharging with a discharge current. The charging and discharging current profile can include the energy storage device being charged and/or discharged with a current in one or more time periods.

During charging and/or discharging of the energy storage device, heat is generated inside the energy storage device by the internal resistance of the energy storage device. The heat is removed and consequently the heat and/or temperatures relating to the energy storage device can be detected during charging and discharging in order to ascertain the heat variable. The heat variable therefore results from the internal resistance and from the charging and discharging. Therefore, time periods are known from the charging and discharging current profile, which can be used together with the heat variable to ascertain the power loss. The internal resistance can be calculated from the power loss.

The advantage of the disclosure lies in it being utilized that the heat generated by the internal resistance is removed from the battery cell(s) of the energy storage device to surroundings of the battery cells. The heat can be detected as heat variable and is caused by the internal resistance. It was discovered that the heat variable has a relationship with the internal resistance. Therefore, the heat variable can be called upon for measurement of the power loss, from which the internal resistance is established precisely.

The determination of the charging and discharging current profile can take place in such a manner that the charging and discharging is carried out to a desired state of charge, wherein the desired state of charge is equal to the actual state of charge. The internal resistance is ascertained over a charge and discharge cycle. Therefore, what is achieved is that ascertaining the internal resistance is independent of the actual state of charge, which typically has an influence on the internal resistance.

The ascertainment of the heat variable can take place by a temperature control device for controlling the temperature of the energy storage device. The energy storage device comprises the temperature control device. It was discovered that an energy storage device of this type typically has the temperature control device for setting and/or controlling temperatures of the energy storage device. Therefore, the energy storage device is set up to detect a heat and/or temperature relating to the energy storage device precisely. The temperature control device can be a cooling device for cooling the energy storage device.

The heat variable can relate to a quantity of heat removed from the energy storage device by the temperature control device. The temperature control device can be a cooling device. The temperature control device removes heat from the energy storage device in order to cool the energy storage device. The heat that is removed can be detected effectively and gives information about the power loss.

The heat variable can relate to a cooling energy for operating the temperature control device for controlling the temperature of the energy storage device to a desired temperature. The temperature control device can be a cooling device. A cooling energy is applied so that the cooling device can be operated. If the charging and discharging current profile is formed, then the desired temperature can be set by the temperature control and in particular cooling of the energy storage device. The cooling power requirement or the cooling energy that is required for forming the desired temperature changes over the life cycle of the battery store with its internal resistance and can be detected effectively. Therefore, effectively and exactly ascertaining the heat variable is possible.

The charging and discharging can comprise drawing from an electricity grid outside the vehicle and feeding into the electricity grid outside the vehicle. In a vehicle-to-grid, V2G, application, the charging and discharging can also be referred to as bidirectional charging. The electricity grid outside the vehicle can for example be a private or public electricity grid. Therefore, electric current can be fed from the electricity grid into the energy storage device and thus drawn from the electricity grid according to the charging and discharging current profile for charging the energy storage device. To discharge the energy storage device according to the charging and discharging current profile, electric current can be fed from the energy storage device into the electricity grid for discharging the energy storage device. In one or more embodiments, the charging and discharging current profile can provide currents for charging and discharging with a comparatively large interval. At the same time, only relatively low requirements are placed on the charging/discharging capacity of the energy storage device. Therefore, the internal resistance can be ascertained effectively and comparatively fast. For a home electricity grid having an electricity-grid energy store, the charging and discharging of the energy storage device may be cost-neutral. In V2G applications, the motor vehicle having the energy storage device is connected to the (commercial or non-commercial) electricity grid. The motor vehicle can be charged or discharged depending on vehicle or infrastructure demand. As a result of this, it is possible to reduce power peaks in the electricity grid. Alternatively, a charging process can for example be time-controlled in order to reduce the electricity costs for a full charge for example.

The charging and discharging can comprise drawing from an electricity grid outside the vehicle and feeding into an on-board electrical system of the motor vehicle. The charging can for example take place at a charging station or a charging point or a charging column. Therefore, electric current can be fed from the electricity grid into the energy storage device and thus drawn from the electricity grid according to the charging and discharging current profile for charging the energy storage device. To discharge the energy storage device according to the charging and discharging current profile, electric current can be fed from the energy storage device into the on-board electrical system for discharging the energy storage device. The current fed into the on-board electrical system can be consumed by electrical consumers of the motor vehicle. For example, current fed into the on-board electrical system can be used for heating and/or cooling an interior or a cabin of the motor vehicle. Therefore, the internal resistance can also be ascertained independently of a V2G application.

That which is described above can, in other words and in relation to one or more embodiments that are described as non-limiting for the present disclosure, be summarized as follows: The disclosure relates in particular to ascertaining the internal resistance of a battery store by active temperature control by the specification of a charging and/or discharging current profile, possibly in combination with the heating/cooling circuit of the vehicle, particularly in vehicle-to-grid, V2G, applications. The temperature or the temperature change of the battery store as a consequence of the specification of the charging/discharging current profile correlates with its internal resistance via the resulting power loss. If the internal resistance changes over the life cycle of the battery store, then the relationship between temperature/temperature change and the specified charging/discharging current profile also changes. If a (possibly predefined) charging/discharging current profile is then formed, then a temperature can be set by the cooling of the store. The cooling power requirement that is required for forming the desired temperature changes over the life cycle of the battery store with its internal resistance. Accordingly, it is possible to draw a conclusion about the internal resistance by the cooling power requirement for setting a particular temperature. This relationship makes it possible to detect a change of internal resistance by the change of the cooling power requirement over the life cycle of the battery store. In vehicle-to-grid (V2G) applications, the battery store of electric vehicles at stationary is charged or discharged in accordance with the demand of the infrastructure. In addition, charging/discharging processes could be initiated by the vehicle in a targeted manner to characterize the state of the store.

Furthermore, a computer program is provided, comprising commands which, during the execution of the program by a computer, cause this computer to execute or carry out the above-described method at least partially.

A program code of the computer program may be present in any desired code, particularly in a code that is suitable for controllers of motor vehicles.

That which is described above with reference to the method also applies analogously for the computer program and vice versa.

Furthermore, a data processing device, e.g. a control unit, for a motor vehicle is provided, wherein the data processing device is set up to execute or carry out the above-described method at least partially. Thus, the method is a computer-implemented method.

The data processing device can for example be included by a battery management unit (BMU). The data processing device may alternatively be an electronic control unit (ECU). The electronic control unit may be an intelligent processor-controlled unit which can communicate with other modules e.g. via a central gateway (CGW) and which can form the vehicle electrical system possibly by field buses, such as the CAN bus, LIN bus, MOST bus and FlexRay or by automotive ethernet, e.g. together with telematic control units. It is conceivable that the control unit controls functions relevant for the performance of the motor vehicle, such as the engine control unit in particular and the drivetrain, and/or regulates a charging process.

That which is described above with reference to the method and to the computer program also applies analogously for the data processing device and vice versa.

Furthermore, a battery management unit for a motor vehicle is provided, comprising the above-described data processing device.

That which is described above with reference to the method, to the data processing device and to the computer program also applies analogously for the battery management unit (BMU) and vice versa.

Furthermore, a motor vehicle is provided, comprising an energy storage device and the above-described data processing device and/or the above-described battery management unit.

The motor vehicle can be a passenger car, particularly an automobile. The optionally automated motor vehicle can be a motor vehicle that can be driven electrically. The motor vehicle may to this end comprise an electric drive that can be loaded with electrical energy, which is provided by the energy storage device, for driving the motor vehicle.

That which is described above with reference to the method, to the data processing device, to the battery management unit and to the computer program also applies analogously for the motor vehicle and vice versa.

Furthermore, a computer-readable medium, particularly a computer-readable storage medium, is provided. The computer-readable medium comprises commands which, during the execution of the program by a computer, cause this computer to execute the above-described method at least partially.

That is to say, a computer-readable medium can be provided, which comprises an above-defined computer program. The computer-readable medium can be any desired digital data storage device, such as for example a USB stick, a hard disk, a CD-ROM, an SD card or an SSD card. The computer program does not necessarily have to be stored on such a computer-readable storage medium in order to be made available to the motor vehicle, but rather can also be obtained via the internet or externally in another way.

That which is described above with reference to the method, to the data processing device, to the battery management unit, to the computer program and to the motor vehicle also applies analogously for the computer-readable medium and vice versa.

Embodiments are described below with reference to the figures.

### BRIEF DESCRIPTION OF THE DRAWINGS

FIG. 1 schematically shows a motor vehicle according to one aspect of the disclosure;

FIG. 2 schematically shows a flow chart of a method according to one aspect of the disclosure.

### DETAILED DESCRIPTION OF THE DRAWINGS

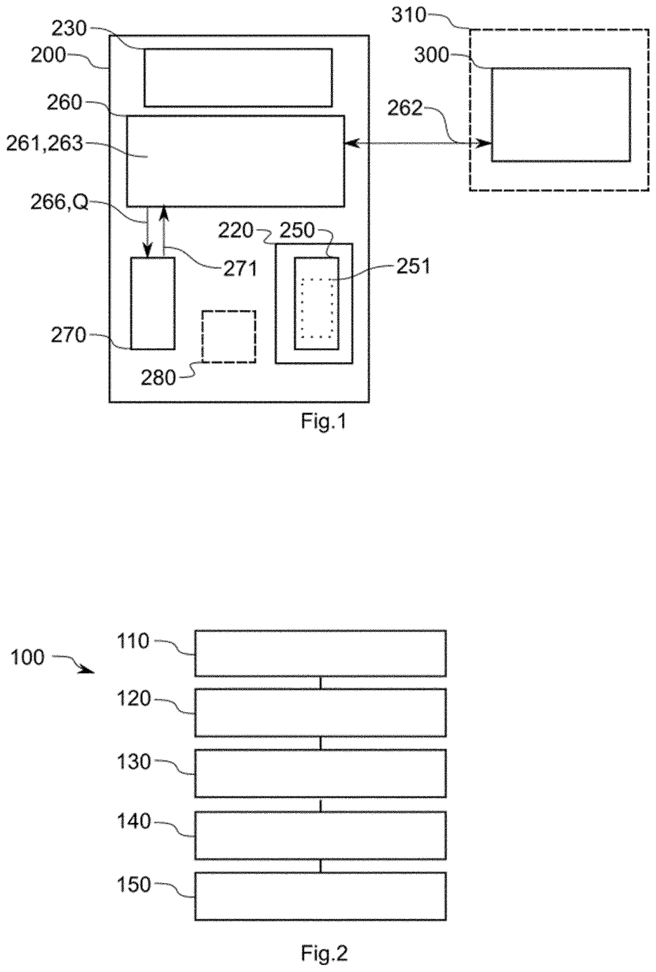

FIG. 1 schematically shows a motor vehicle 200 according to an aspect of the disclosure. The motor vehicle 200 is a motor vehicle 200 that can be driven electrically. For this, the motor vehicle 200 has an electric drive 230 and an energy storage device 260. The energy storage device 260 can load the electric drive 230 with electrical energy which the electric drive 230 can convert into mechanical energy. A state of charge of the energy storage device 260 falls.

A current state of charge of the energy storage device 260 is characterized by an actual state of charge 261. During discharging of the energy storage device 260, the actual state of charge 261 falls and during charging of the energy storage device 260, the actual state of charge 261 increases. The energy storage device 260 is rechargeable. The energy storage device 260 can be loaded with electric current for charging and the energy storage device 260 can provide an electric current for discharging. During charging and during discharging of the energy storage device 260, heat is created by an internal resistance 263 of the energy storage device 260.

The motor vehicle 200 has a temperature control device 270. The temperature control device 270 is set up to set a desired temperature 271 of the energy storage device 260. For this, the temperature control device 270 has a fan, a circulation pump and/or a heat transfer fluid for example. The temperature control device 270 is a cooling device in particular. A quantity of heat Q is removed from the energy storage device 260 to the temperature control device 270. By removing the quantity of heat Q from the energy storage device 260, a temperature of the energy storage device 271 may fall and/or increase less strongly than without and/or with an inactive temperature control device 270.

For charging the energy storage device 260, the energy storage device 260 or the motor vehicle 200 can be electrically connected to a charging station 300 outside the vehicle. The charging station 300 is part of an electricity grid 310 outside the vehicle. Power is supplied to the charging station 300 from the electricity grid 310 outside the vehicle. Thus, the energy storage device 260 can be charged by current from the electricity grid 310 to a desired state of charge 262 and/or discharged.

The discharging of the energy storage device 260 takes place by feeding an electric current from the energy storage device 260 into the electricity grid 310 outside the vehicle.

Alternatively or additionally, the discharging of the energy storage device 260 takes place by electrical consumers (not shown) of the motor vehicle 200, wherein the electric current is fed from the energy storage device 260 into an on-board electrical system 280 included by the motor vehicle 200. For this, the motor vehicle 200 has electrical consumers that are electrically connected to the on-board electrical system 280, for example a heating and/or cooling device for controlling the temperature of an interior or a cabin of the motor vehicle 200.

The motor vehicle 200 is set up to carry out the method 100 that is described with reference to FIG. 2. For this, the motor vehicle 200 according to FIG. 1 has a data processing device 250 and a battery management unit 220 in addition to the energy storage device 260. In one or more embodiments, the battery management unit 220 comprises the data processing device 250. The data processing device 250 may however be independent of the battery management unit 220.

The data processing device 250 is set up for determining a charging and discharging current profile 251 for charging the energy storage device 260 by a charging station 300 outside the vehicle and for discharging the energy storage device 260 based on the actual state of charge 261. The determination 120 of the charging and discharging current profile 251 takes place in such a manner that the charging and discharging 130 is carried out to a desired state of charge 262, wherein the desired state of charge 262 is equal to the actual state of charge 261. The charging and discharging current profile 251 comprises a charging current profile and a discharging current profile. The charging current profile of the charging and discharging current profile 251 can be determined as described in DE 10 2019 108 607 B3. The charging capacity of the energy storage device 260 and a charging power of the charging station 300 are taken into account in particular.

The battery management unit 220 is set up to carry out charging and discharging 130 of the energy storage device 260 based on the charging and discharging current profile 251. The energy storage device 260 is loaded with an electric current for charging over time intervals determined by the charging and discharging current profile and/or an electric current is drawn from the energy storage device 260 for discharging according to time intervals determined by the charging and discharging current profile.

The charging and discharging 130 comprises drawing from the electricity grid 310 outside the vehicle and feeding into the electricity grid 310 outside the vehicle. The discharging current profile of the charging and discharging current profile 251 is ascertained for example taking an infeed power into consideration, that is to say a power of a current for feeding from the energy storage device 260 into the electricity grid 310.

Alternatively or additionally, the charging and discharging 130 comprises drawing from the electricity grid 310 outside the vehicle and feeding into the on-board electrical system 280 of the motor vehicle 200. The discharging current profile of the charging and discharging current profile 251 is ascertained for example taking a power consumption into consideration, that is to say a power of an electrical consumer of the motor vehicle 200.

The data processing device 250 is set up to ascertain a heat variable 266 relating to the charging and discharging 130 during and/or after the charging and discharging 130. The ascertainment 140 of the heat variable 266 takes place by a temperature control device 270 for controlling the temperature of the energy storage device 260.

The data processing device 250 is set up for ascertaining a power loss based on the charging and discharging current profile 251 and based on the heat variable 266 for determining the internal resistance 263. The heat variable 266 relates to a cooling energy for operating the temperature control device 270 for controlling the temperature of the energy storage device 260 to a desired temperature 271. The cooling energy results in particular from a time interval in which the temperature control device 270 carries out a cooling of the energy storage device 260 with an adjustable and/or measurable cooling power.

Alternatively or additionally, the heat variable 266 relates to the quantity of heat Q removed from the energy storage device 260 by the temperature control device 270. The quantity of heat Q removed can be ascertained for example by temperature changes of the energy storage device 260, the temperature control device 270 and/or a heat transfer fluid of the temperature control device 270 in particular. The temperature changes can be measured by temperature sensors (not shown).

FIG. 2 schematically shows a flow chart of a method 100 according to an aspect of the disclosure. The method 100 is a method 100 for determining an internal resistance 263 of an energy storage device 260 of a motor vehicle 200. A motor vehicle 200 of this type is described with reference to FIG. 1. FIG. 2 is described with reference to FIG. 1.

The method 100 includes: ascertaining 110 an actual state of charge 261 of the energy storage device 260.

Determination 120 takes place of a charging and discharging current profile 251 for charging the energy storage device 260 by a charging station 300 outside the vehicle and for discharging the energy storage device 260 based on the actual state of charge 261. The determination 120 of the charging and discharging current profile 251 takes place in such a manner that the charging and discharging 130 is carried out at a desired state of charge 262, wherein the desired state of charge 262 is equal to the actual state of charge 261.

Charging and discharging 130 of the energy storage device 260 takes place based on the charging and discharging current profile 251.

Ascertainment 140 of a heat variable 266 relating to the charging and discharging 130 takes place. The ascertainment 140 of the heat variable 266 takes place by a temperature control device 270 for controlling the temperature of the energy storage device 260.

Ascertainment 150 of a power loss takes place based on the charging and discharging current profile 251 and based on the heat variable 266 for determining the internal resistance 263.

### List of Reference Signs

100 Method
110 Ascertaining an actual state of charge
120 Determining a charging and discharging current profile
130 Charging and discharging
140 Ascertaining a heat variable
150 Ascertaining a power loss
200 Motor vehicle
220 Battery management unit
230 Electric drive
250 Data processing device
251 Charging and discharging current profile
260 Energy storage device
261 Actual state of charge
262 Desired state of charge
263 Internal resistance
266 Heat variable
270 Temperature control device
271 Desired temperature
280 On-board electrical system
300 Charging station
310 Electricity grid
Q Quantity of heat

1-11. (canceled)

12. A method for determining an internal resistance of an energy storage device of a motor vehicle, wherein the method comprises:
ascertaining an actual state of charge of the energy storage device;
determining a charging and discharging current profile for charging the energy storage device by a charging station outside the motor vehicle and for discharging the energy storage device based on the actual state of charge;
charging and discharging the energy storage device based on the charging and discharging current profile;
ascertaining a heat variable relating to the charging and discharging; and
ascertaining a power loss based on the charging and discharging current profile and based on the heat variable for determining the internal resistance.

13. The method according to claim 12, wherein the charging and discharging current profile is determined based on the charging and discharging being carried out to a desired state of charge, wherein the desired state of charge is equal to the actual state of charge.

14. The method according to claim 12, wherein the heat variable is ascertained by a temperature control device configured to control a temperature of the energy storage device.

15. The method according to claim 14, wherein the heat variable relates to a quantity of heat removed from the energy storage device by the temperature control device.

16. The method according to claim 14, wherein the heat variable relates to a cooling energy for operating the temperature control device for controlling the temperature of the energy storage device to a desired temperature.

17. The method according to claim 12, wherein the charging and discharging comprises drawing from an electricity grid outside the motor vehicle and feeding into the electricity grid outside the motor vehicle.

18. The method according to claim 12, wherein the charging and discharging comprises drawing from an electricity grid outside the motor vehicle and feeding into an on-board electrical system of the motor vehicle.

19. A computer-readable medium having stored thereon a computer program which, during execution of the computer program by a computer, causes the computer to carry out a method for determining an internal resistance of an energy storage device of a motor vehicle, the method comprising:
ascertaining an actual state of charge of the energy storage device;
determining a charging and discharging current profile for charging the energy storage device by a charging station outside the motor vehicle and for discharging the energy storage device based on the actual state of charge;
charging and discharging the energy storage device based on the charging and discharging current profile;
ascertaining a heat variable relating to the charging and discharging; and
ascertaining a power loss based on the charging and discharging current profile and based on the heat variable for determining the internal resistance.

20. The computer-readable medium according to claim 19, wherein the charging and discharging current profile is determined based on the charging and discharging being carried out to a desired state of charge, wherein the desired state of charge is equal to the actual state of charge.

21. The computer-readable medium according to claim 19, wherein the heat variable is ascertained by a temperature control device configured to control a temperature of the energy storage device.

22. The computer-readable medium according to claim 21, wherein the heat variable relates to a quantity of heat removed from the energy storage device by the temperature control device.

23. The computer-readable medium according to claim 21, wherein the heat variable relates to a cooling energy for operating the temperature control device for controlling the temperature of the energy storage device to a desired temperature.

24. The computer-readable medium according to claim 19, wherein the charging and discharging comprises:
drawing from an electricity grid outside the motor vehicle and feeding into the electricity grid outside the motor vehicle; or drawing from the electricity grid outside the motor vehicle and feeding into an on-board electrical system of the motor vehicle.

25. A motor vehicle, comprising:
an energy storage device; and
a battery management unit comprising a data processing device configured to carry out a method for determining an internal resistance of the energy storage device of the motor vehicle, the method comprising:
ascertaining an actual state of charge of the energy storage device;
determining a charging and discharging current profile for charging the energy storage device by a charging station outside the motor vehicle and for discharging the energy storage device based on the actual state of charge;
charging and discharging the energy storage device based on the charging and discharging current profile;
ascertaining a heat variable relating to the charging and discharging; and
ascertaining a power loss based on the charging and discharging current profile and based on the heat variable for determining the internal resistance.

26. The motor vehicle according to claim 25, wherein the charging and discharging current profile is determined based on the charging and discharging being carried out to a desired state of charge, wherein the desired state of charge is equal to the actual state of charge.

27. The motor vehicle according to claim 25, wherein the heat variable is ascertained by a temperature control device configured to control a temperature of the energy storage device.

28. The motor vehicle according to claim 27, wherein the heat variable relates to a quantity of heat removed from the energy storage device by the temperature control device.

29. The motor vehicle according to claim 27, wherein the heat variable relates to a cooling energy for operating the temperature control device for controlling the temperature of the energy storage device to a desired temperature.

30. The motor vehicle according to claim 25, wherein the charging and discharging comprises drawing from an electricity grid outside the motor vehicle and feeding into the electricity grid outside the motor vehicle.

31. The motor vehicle according to claim 25, wherein the charging and discharging comprises drawing from an electricity grid outside the motor vehicle and feeding into an on-board electrical system of the motor vehicle.
